(19) United States
(12) Patent Application Publication
(10) Pub. No.: US 2025/0164531 A1
(43) Pub. Date: May 22, 2025

(54) CURRENT SENSOR INTEGRATED CIRCUIT HAVING DIFFERENT CURRENT PATH WIDTHS FOR DETECTING STRAY FIELDS

(71) Applicant: Allegro MicroSystems, LLC, Manchester, NH (US)

(72) Inventor: William P. Taylor, Amherst, NH (US)

(73) Assignee: Allegro MicroSystems, LLC, Manchester, NH (US)

(21) Appl. No.: 18/882,963

(22) Filed: Sep. 12, 2024

Related U.S. Application Data
(63) Continuation-in-part of application No. 18/512,122, filed on Nov. 17, 2023.

(51) Int. Cl. G01R 15/20

(52) U.S. Cl. CPC G01R 15/207; G01R 15/202; G01R 15/205

(57) ABSTRACT

Methods and apparatus for a current sensor integrated circuit package including a current conductor, which may be a loop, having regions of different widths and first and second magnetic field sensing elements positioned in relation to the current loop. The first magnetic field sensing element generates a first output signal and the second magnetic field sensing element generates a second output signal. An adjustment circuit adjusts the output of the first magnetic field sensing element to generate an adjusted signal for the first magnetic field sensing element that is same as the second output signal. A diagnostic module receives the adjusted signal for the first magnetic field sensing element and the output of the second output signal to detect a presence of a stray field.

### CROSS REFERENCE TO RELATED APPLICATIONS

This application is a continuation-in-part of U.S. patent application Ser. No. 18/512,122 filed on Nov. 17, 2023, entitled “CURRENT SENSOR INTEGRATED CIRCUIT,” the entire content of which is incorporated herein by reference.

### BACKGROUND

As is known in the art, conventional magnetic field current sensors sense current in a current-carrying conductor via a magnetic field generated by the current through the conductor. The current sensor generates an output signal having a magnitude proportional to the magnetic field induced by the current through the conductor. Stray fields may degrade sensor performance.

### SUMMARY

Example embodiments of the disclosure provide method and apparatus for a current sensor comprising a leadframe that includes a current loop with first and second portions having different widths. In one embodiment, one region of the current loop has a narrowed region, which may be formed by a notch. Magnetic field sensing elements can be positioned in relation to the narrowed region and non-narrowed regions of the current loop to detect the presence of stray fields. In embodiments, one or more of the magnetic field sensing element output signals can be adjusted so that signals having the same level are generated in the absence of a stray field. If these signals diverge more than a selected amount, this may be due to the presence of a stray field. In embodiments, a diagnostic module can monitor signal levels to detect stray fields and generate signals, such as alerts, to indicate the presence of a stray field.

In one aspect, a current sensor integrated circuit package comprises: a current conductor having regions of different widths; first and second magnetic field sensing elements positioned in relation to the current conductor, wherein the first magnetic field sensing element generates a first output signal and the second magnetic field sensing element generates a second output signal; and an adjustment circuit to adjust the output of the first magnetic field sensing element to generate an adjusted signal for the first magnetic field sensing element that is same as the second output signal; and a diagnostic module configured to receive the adjusted signal for the first magnetic field sensing element and the output of the second output signal to detect a presence of a stray field.

A package can further include one or more of the following features: the current conductor comprises a loop, the loop has a U-shape, a further adjustment circuit to adjust the output of the second magnetic field sensing element to generate an adjusted signal for the second magnetic field sensing element for the diagnostic module, the current conductor includes a first width and a narrowed region having a second width less than the first width, the narrowed region comprises a notch, the first magnetic field sensing element is positioned in relation to the narrowed region and the second magnetic field is positioned in relation to a portion of the current conductor having the first width, the current conductor comprises a U-shaped loop having first and second sides and a bottom, wherein the narrowed region is located in the second side of the current loop, the first magnetic field sensing element comprises a Hall element, the first magnetic field sensing element comprises a magnetoresistive element, the second magnetic field sensing element comprises a Hall element, an adjustment circuit to adjust the output signal level of the first magnetic field sensing element, a diagnostic module coupled to the adjustment circuit to detect divergence of the adjusted output signal level of the first magnetic field sensing element and the output signal level of the second magnetic field sensing element more than a selected amount corresponding to the detection of the stray field, the current conductor is linear in shape, an on-chip coil proximate the first and/or second magnetic field sensing elements for generating a test magnetic field to simulate the stray field, a first terminal to output a first output signal corresponding to the output of the first magnetic field sensing element, a second terminal to output a second output signal corresponding to the output of the second magnetic field sensing element, and/or an output terminal to output a diagnostic signal indicating the presence of the stray field above a threshold.

In another aspect, a method comprises: employing a current conductor, which forms part of a current sensor integrated circuit package, having regions of different widths; positioning first and second magnetic field sensing elements in relation to the current conductor, wherein the first magnetic field sensing element generates a first output signal and the second magnetic field sensing element generates a second output signal; and adjusting, using an adjustment circuit, the output of the first magnetic field sensing element to generate an adjusted signal for the first magnetic field sensing element that is same as the second output signal; and configuring a diagnostic module to receive the adjusted signal for the first magnetic field sensing element and the output of the second output signal to detect a presence of a stray field.

A method can further include one or more of the following features: the current conductor comprises a loop, the loop has a U-shape, a further adjustment circuit to adjust the output of the second magnetic field sensing element to generate an adjusted signal for the second magnetic field sensing element for the diagnostic module, the current conductor includes a first width and a narrowed region having a second width less than the first width, the narrowed region comprises a notch, the first magnetic field sensing element is positioned in relation to the narrowed region and the second magnetic field is positioned in relation to a portion of the current conductor having the first width, the current conductor comprises a U-shaped loop having first and second sides and a bottom, wherein the narrowed region is located in the second side of the current loop, the first magnetic field sensing element comprises a Hall element, the first magnetic field sensing element comprises a magnetoresistive element, the second magnetic field sensing element comprises a Hall element, an adjustment circuit to adjust the output signal level of the first magnetic field sensing element, a diagnostic module coupled to the adjustment circuit to detect divergence of the adjusted output signal level of the first magnetic field sensing element and the output signal level of the second magnetic field sensing element more than a selected amount corresponding to the detection of the stray field, the current conductor is linear in shape, an on-chip coil proximate the first and/or second magnetic field sensing elements for generating a test magnetic field to simulate the stray field, a first terminal to output a first output signal corresponding to the output of the first magnetic field sensing element, a second terminal to output a second output signal corresponding to the output of the second magnetic field sensing element, and/or an output terminal to output a diagnostic signal indicating the presence of the stray field above a threshold.

### BRIEF DESCRIPTION OF DRAWINGS

The foregoing features of this disclosure, as well as the disclosure itself, may be more fully understood from the following description of the drawings in which:

FIG. 1 is a schematic representation of an example current sensor having a notched leadframe;

FIG. 2A is a partially transparent top view of a current sensor having a notched leadframe;

FIG. 2B shows the current sensor of FIG. 2A without a die;

FIG. 2C shows a side view of the IC of FIG. 2B with the leadframe having a thickness T;

FIG. 3 shows a portion of the sensor of FIG. 2B in additional detail;

FIG. 3A shows a portion of a sensor having a U-shaped notched leadframe and sensing elements;

FIG. 3B shows a portion of a sensor having a U-shaped notched leadframe with a range of locations for the sensing elements;

FIG. 4A is a graphical representation of percent change in coupling due to leadframe for a conventional sensor having a TMR magnetic field sensing element; and FIG. 4B is a graphical representation percent change in coupling due to leadframe for a sensor having a TMR magnetic field sensing element and notched leadframe;

FIG. 5A is a partially transparent top view, FIG. 5B is a partially transparent isometric view, and FIG. 5C is an isometric view of an example current sensor IC package having a notched leadframe in a throat of a current sensing loop;

FIG. 6 shows a portion of sensor having a U-shaped leadframe with a narrowed region in one region with first and second magnetic field sensing elements positioned to detect a stray field;

FIG. 6A shows an example circuit implementation to adjust an output of one of the magnetic field sensing elements so it is the same as the other output;

FIG. 6B shows an example digital implementation to adjust one or more outputs of magnetic field sensing elements for detecting signal divergence due to the presence of stray fields;

FIG. 7 shows a portion of a sensor having a U-shaped leadframe with various magnetic field positioning to detect stray fields;

FIG. 8 is a portion of an example sensor having a U-shaped leadframe with a narrowed region in one region with MR magnetic field sensing elements positioned to detect a stray field; and

FIG. 9 is a flow diagram to show example steps for providing a sensor having a current conductive with various magnetic field positioning to detect stray fields.

### DETAILED DESCRIPTION

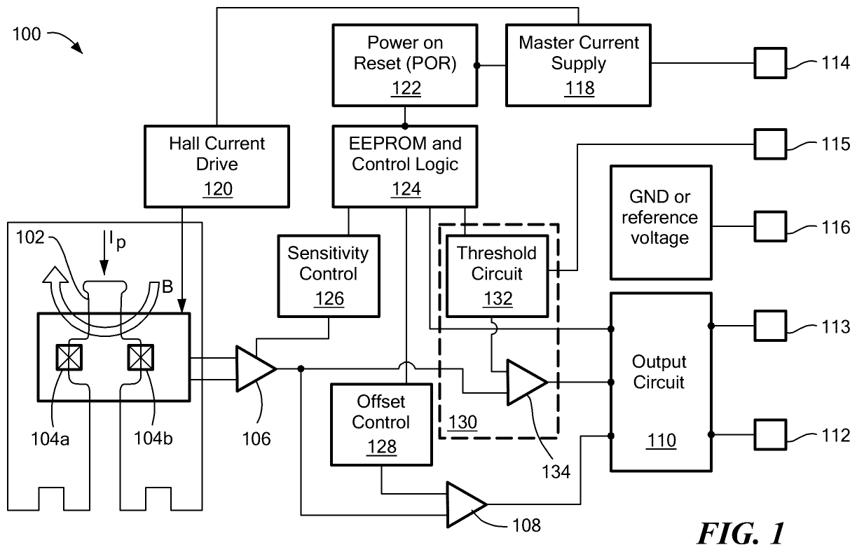

FIG. 1 shows an example circuit block diagram for a current sensor integrated circuit 100 having a leadframe with a current conductor loop. A current Iₚ flows through a current conductor loop 102 and generates a magnetic field that can be sensed by first and second magnetic field sensing elements 104a,b, such as Hall effect plates for example. The magnetic field results in the Hall effect plates 104a,b providing a signal to a front-end amplifier 106. The front-end amplifier 106 provides an output to amplifier 108, which may be a linear amplifier, which feeds into an output circuit 110. Output circuit 110 may be a digital or analog circuit that provides an output to at least one bond pad 112. The output represents the magnetic field measured and amplified through the amplifier 108. Other numbers of output bond pads more than two may also be provided.

Bond pad 114 provides a voltage and current input, typically Vcc, to provide power to the integrated circuit 100. A ground bond pad 116 may be provided to integrated circuit 100. Input bond pad 114 is coupled to a master current supply circuit 118 that provides power to the circuitry within integrated circuit 100. Although master current supply 118 is provided as a current supply, it would be apparent that voltages may also be provided to the circuits on integrated circuit 100. A Hall effect current drive circuit 120 takes current (or voltage) from the master current supply 118 and provides a regulated current to the Hall Effect sensing elements 104a,b. The master current supply 118 also provides power to a power on reset circuit 122. The power on reset circuit monitors the power coming into the circuit 100 and provides a signal to EEPROM and control logic circuit 124. The power on reset circuit 122 and EEPROM and control logic circuit 124 are used to configure and enable the integrated circuit, including the output circuit 110.

The EEPROM and control circuit 124 provides a signal to a sensitivity control circuit 126 which provides a signal to the front end amplifier 106 to adjust the sensitivity of the front end amplifier. The adjustment may be the result of a change in the power level in the circuit 100, or as a result of a temperature change of the circuit. An example of a temperature sensor circuit may include but is not limited to a diode temperature sensor, or the use of known temperature compensation resistors.

The EEPROM and control circuit 124 provides a signal to an offset control circuit 128. The offset control circuit 128 provides a signal to the amplifier 108. The offset control circuit 128 allows the circuit 100 to adjust the offset of the amplifier 108 for changes in power or temperature (the temperature compensation circuit is not shown) or a combination of temperature and power changes. The offset control circuit 128 may also provide adjustment for other offset sources, such as a stress in the integrated circuit die.

An input lead 115 may be provided to set a threshold for a fault indication circuit 130 (i.e., provide a fault trip level). In an embodiment, the input lead 115 provides a fault voltage level. The fault indication circuit 130 can include a threshold circuit 132 and a fault comparator 134. The EEPROM and control circuit 124 provides an input to the threshold circuit 132. The threshold circuit 132 provides a signal to the fault comparator 134, which compares the output of threshold circuit 132 with the output of the front end amplifier 106 to indicate when a fault exists to the output circuit block 110. The output circuit generates a fault output at output bond pad 113. The fault output may indicate an overcurrent condition in which the current sensed in the current conductor path exceeds a fault trip level, which trip level may be provided in the form of a fault voltage level on bond pad 115. The fault allows, in one example, the user of the current sensor package to turn off the current in the primary current path in order to prevent a high current condition in an electrical circuit.

It is understood that any of the above-described processing may be implemented in hardware, firmware, software, or a combination thereof. Processing may be implemented in computer programs executed on programmable computers/machines that each includes a processor, a storage medium or other article of manufacture that is readable by the processor (including volatile and non-volatile memory and/or storage elements), at least one input device, and one or more output devices. Program code may be applied to data entered using an input device to perform processing and to generate output information.

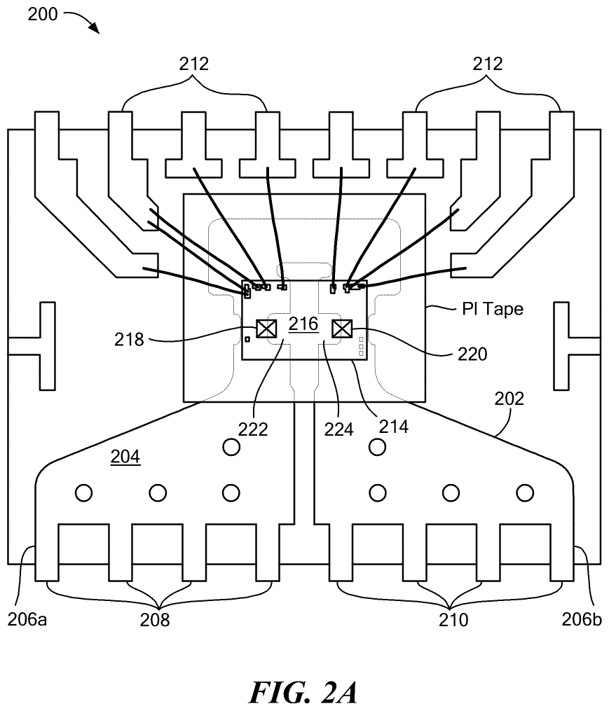

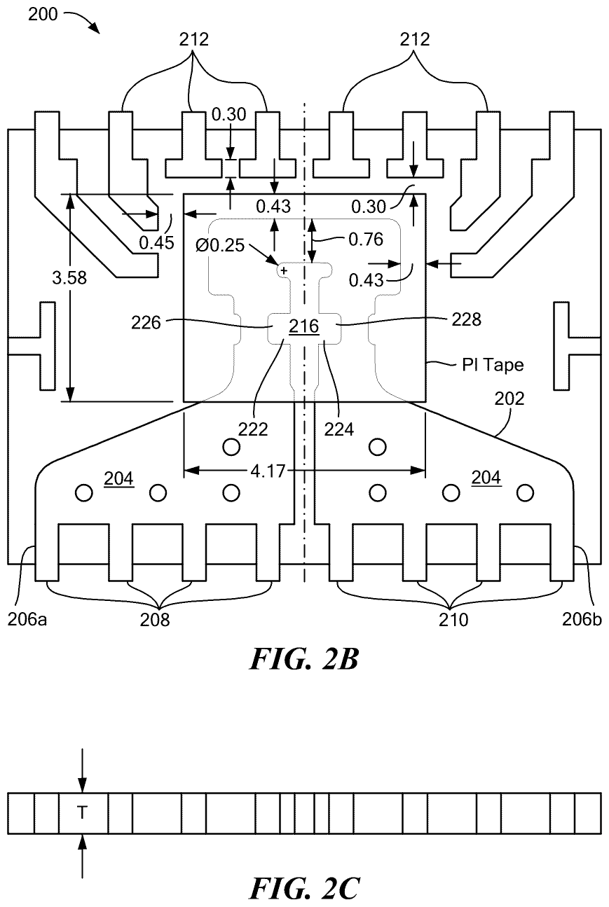

FIGS. 2A and 2B shows a packaged current sensor integrated circuit (IC) 200 including a leadframe 202 with a current conductor loop 204 having first and second ends 206a,b through which current flows in either direction. In the illustrated embodiment, one side of the leadframe 202 has a first series of terminals 208 electrically coupled to the first end 206a of the leadframe and a second series of terminals 210 coupled to the second end 206b. The other side of the leadframe 202 has a number of terminals 212 that can be connected to a die 214, such as via wirebonds. FIG. 2B shows the IC 200 without the die 214. FIG. 2C shows a side view of the IC 200 of FIG. 2B with the leadframe having a thickness T. In embodiments, polyimide (PI) tape can provide electrical isolation.

The current conductor loop 204, which has a generally U-shape, includes a throat region 216 about which current flows to change direction from into the throat to out of the throat. In the illustrated embodiment, the die 214 includes a first magnetic field sensing element 218 and a second magnetic field sensing element 220. The first magnetic field sending element 218 is positioned in relation to a first notch 222 in the throat region 216 of the leadframe and the second magnetic field sensing element 220 is positioned in relation to a second notch 224 in the throat region 216. In the illustrated embodiment (see FIGS. 2A and 2B), the first magnetic field sensing element 218 is aligned with a bottom 226 of the first notch 222 and the second magnetic field sensing element 220 is aligned with a bottom 228 of the second notch 224. In the illustrated embodiment, the first and second field sensing elements 218, 220 straddle respective edges of the notch bottoms 226, 228. As used here, the term straddle means that at least a portion of the respective magnetic field sensing element overlaps with a respective conductive edge of the notch.

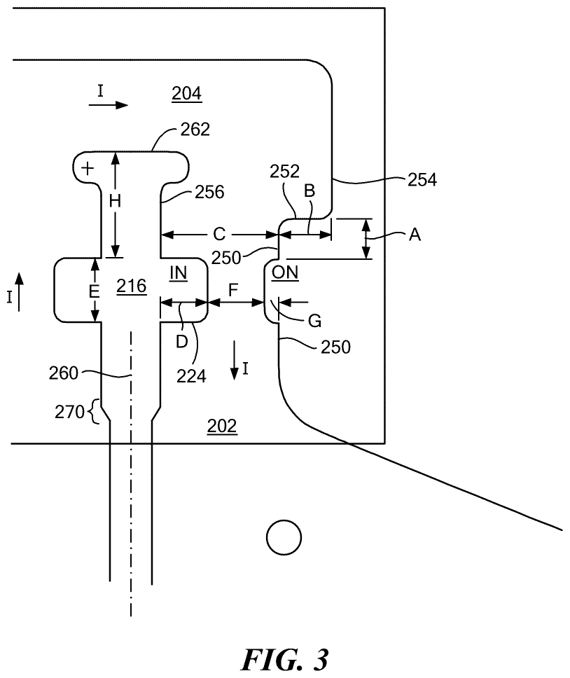

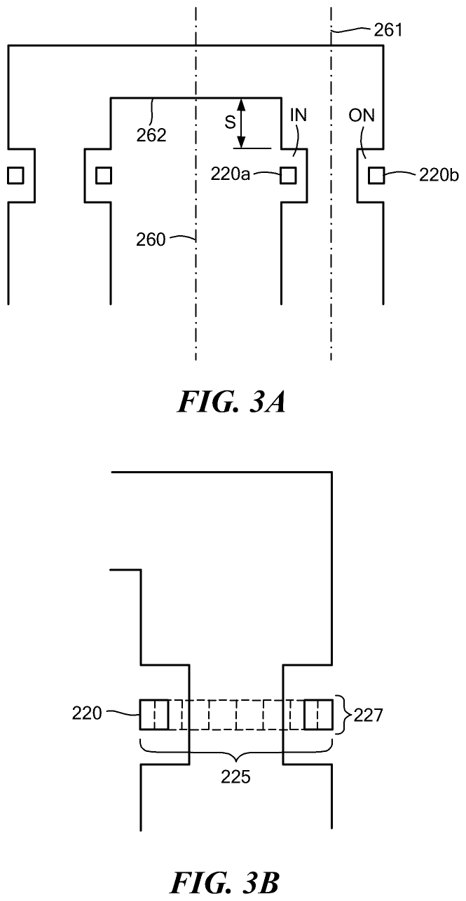

FIG. 3 shows more detail of the second notch 224 in the leadframe 202. This area of the leadframe can be referred to as a busbar through which current to be measured flows. In general, the direction of current should follow the U-shape, e.g., flow in a generally linear direction into the U-shape, change direction at the turn in the U-shape, and flow in a generally linear direction out of the U-shape. The direction of the current in relation to the position of the magnetic field sensing elements can be controlled by a geometry of the notches and throat region to meet the needs of a particular application. For example, the type of magnetic field sensing element may be a factor in positioning the magnetic field sensing elements in relation to the notch geometry and edge locations.

In the illustrated embodiment, the second notch 224 region of FIG. 2 is shown in more detail. The second notch 224 can be considered an inner notch IN which may be sized in relation to an optional outer notch ON, which may be indented from surface 250 and displaced a distance A from surface 252. A distance B corresponds to the spacing of surface 250 and surface 254 of the leadframe. A distance C extends from a non-notched surface 256 in the region of the throat 216 to surface 250. A depth of the inner notch IN is defined by distance D extending from surface 256. A distance F extends from respective bottoms of the inner notch IN and outer notch ON. Distance F is the thinnest part of the leadframe 202 in the throat 216. A depth of the outer notch ON is defined by distance G extending from surface 250. A thickness T of the leadframe is shown in FIG. 2C.

It is understood that the width, depth, geometries, and ratios to lengths and widths of the notch and leadframe can vary to meet the needs of a particular application and achieve desired sensor performance characteristics.

In example embodiments of the sensor, a distance E (width) of the first notch IN is at least twice a distance D (depth) of the first notch to avoid current crowding in this narrowest part of the leadframe. In example embodiments, the distance E ranges from two to fourth times the distance D of the first notch.

In example embodiments, the distance E is at least two times the thickness T of the leadframe. It is understood that 8 mil and 12 mil are common leadframe thicknesses, however, any suitable leadframe thickness can be used to meet the needs of a particular application. In embodiments, distance E is between 2 and 3.5 times leadframe thickness T.

In embodiments, it may be desirable to space the notch IN from the bottom of the U where the current I changes direction so that the direction of current flow is generally parallel to an axis 260 of the throat 216 when passing by the sensing elements. In the illustrated embodiment, the notches IN, ON are spaced by distance A from surface 252. A distance H defines a distance from a bottom 262 of the U-shaped to the beginning of the inner notch IN. In embodiments, distance A enables selection of a distance from a beginning of the notch indentation to a narrowest part of the leadframe at distance F. In example embodiments, distance A is within a range of 60% to 80% of the distance F. It can be seen that distance C=D+F+G.

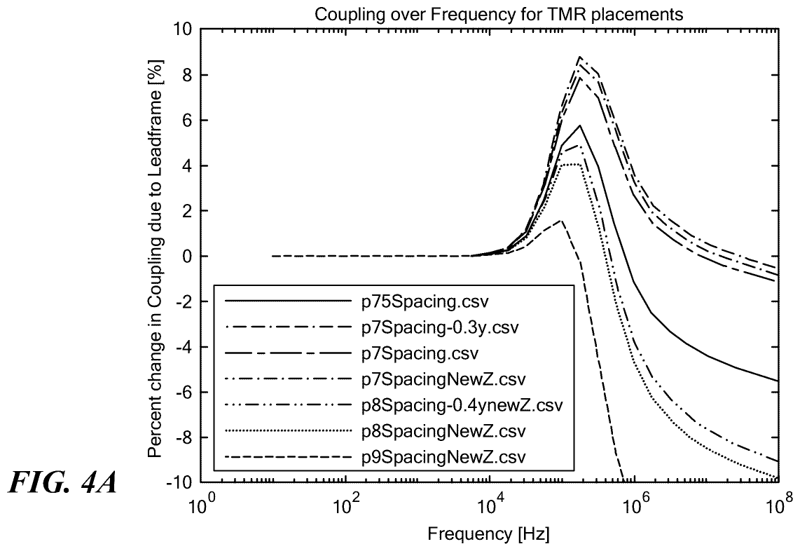

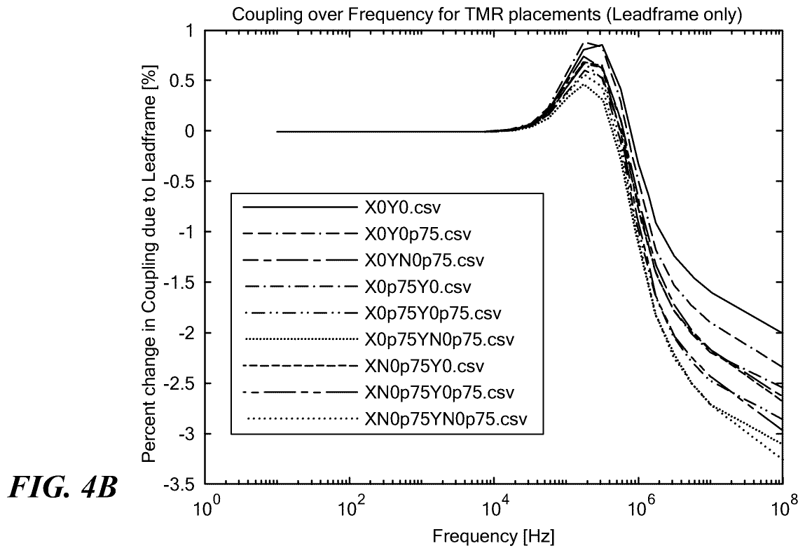

In embodiments, the notches are formed to achieve sensor performance characteristics (see, e.g., FIGS. 4A, 4B). In the illustrated embodiment, the inner notch IN has a distance E that is larger than distance F. In example embodiments, distance E is in a range of two to three times distance F.

In the illustrated embodiment, the leadframe includes a taper region 270 in which the distance between the U-portions of the leadframe increases in distance approaching the throat region 216.

FIG. 3A shows a sensor having inner and outer notches IN, ON that are symmetrical in width and depth with pairs of magnetic field sensing elements 220a,220b also located symmetrically with respect to each other and with respect to an axis 261 parallel to the axis of 260 the throat. The magnetic field sensing elements 220 can be spaced a distance S from a bottom 262 of the U-shaped current conductor. In example embodiments, the distance S is between two and three times leadframe thickness and two and three times a width of the notch. It is understood that any suitable number and type of magnetic field sensing element in a variety of locations to meet the needs of a particular application, such as to maximize flux capture.

As shown in FIG. 3B, a magnetic field sensing element 220 can be located at any suitable location along a first span 225, which is shown as horizontal on the page, and along a second span 227, which is shown as vertical. The magnetic field 220 can be located based on a variety of factors including current vector characteristics, expect current levels, notch geometry, frequency, type of sensing element, and the like. For example, magnetoresistive (MR) sensing elements may not overlap with an edge of the notches and be centered over conductive leadframe material.

In conventional notchless sensors, high speed current sensing with an integrated leadframe poses challenges for signal magnitude and signal flatness over a wide band of input frequency. Skin effects move charge within the leadframe which can change the coupling to the magnetic sensing element, and the SNR/sensitive direction of the transducer can require strange shapes of the conductor to concentrate field on the element.

In example embodiments, a current sensor includes a looped leadframe with sections necked down to concentrate magnetic field in the sensing area of the throat to increase signal on the sensing elements. Smaller feature sizes in this area increase the frequency at which skin effects occur and reduce the total charge movement even when skin effects do occur. A pair of sensing elements in the current loop allows differential sensing. In some embodiments, half etching of the leadframe where the notches are located can improve performance. In some embodiments, the leadframe can be laminated to reduce eddy effects.

FIG. 4A shows percent change in coupling due to leadframe for a conventional sensor having a TMR magnetic field sensing element and FIG. 4B shows percent change in coupling due to leadframe for a sensor having a TMR magnetic field sensing element and notched leadframe. As can be seen, in example sensor embodiments notches and magnetic field sensing element positions combine to present a relatively flat magnetic field over frequency in the sensitive direction of the TMR. As can be seen, without the notches the magnetic field on the TMR elements changes dramatically at 1 MHz input current as the charge moves away from the center of the leadframe and towards the edges. This peaking goes up to +8% depending on the placement of the TMR, and down to −10%. With the notches, this peaking reduces considerably to within +1%.

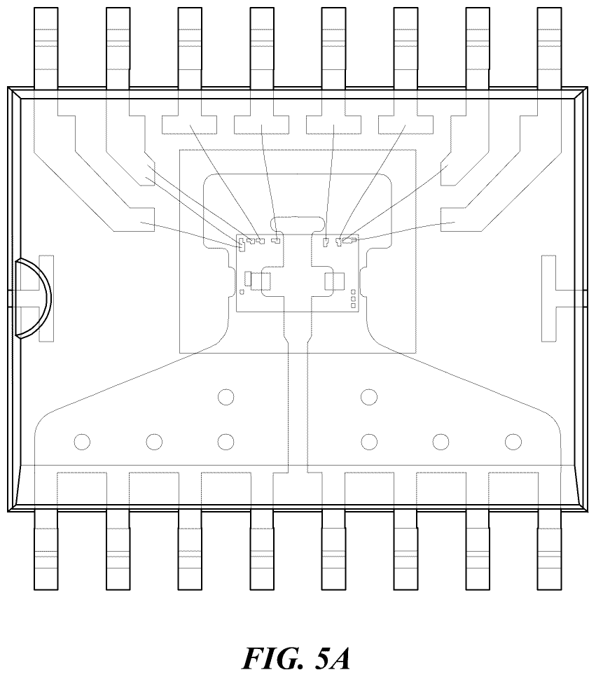

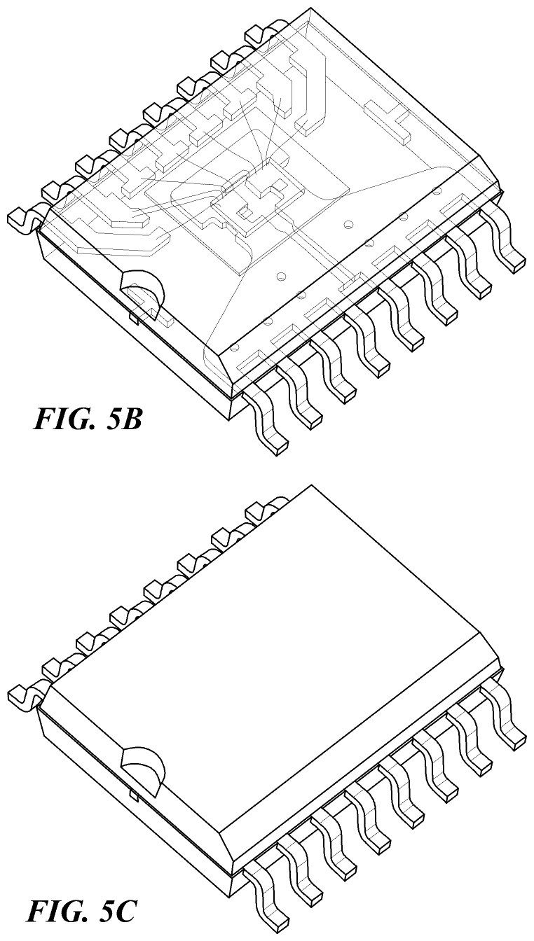

FIG. 5A is a partially transparent top view, FIG. 5B is a partially transparent isometric view, and FIG. 5C is an isometric view of an example current sensor IC package having a notched leadframe in a throat of a current sensing loop.

In another aspect of the disclosure, a current sensor includes a leadframe having a current loop with first and second portions having different widths. In one embodiment, one side of a U-shaped current loop has a narrowed region, which may be formed by a notch. Magnetic field sensing elements can be positioned in relation to the narrowed region and non-narrowed regions of the current loop to detect the presence of stray fields. In embodiments, one or more of the magnetic field sensing element output signals can be adjusted so that similar signals are generated in the absence of a stray field. If these signals diverge by more than a selected amount, this may be due to the presence of a stray field. In embodiments, a diagnostic module can monitor signal levels to detect stray fields and generate signals, such as alerts, to indicate the presence of a stray field.

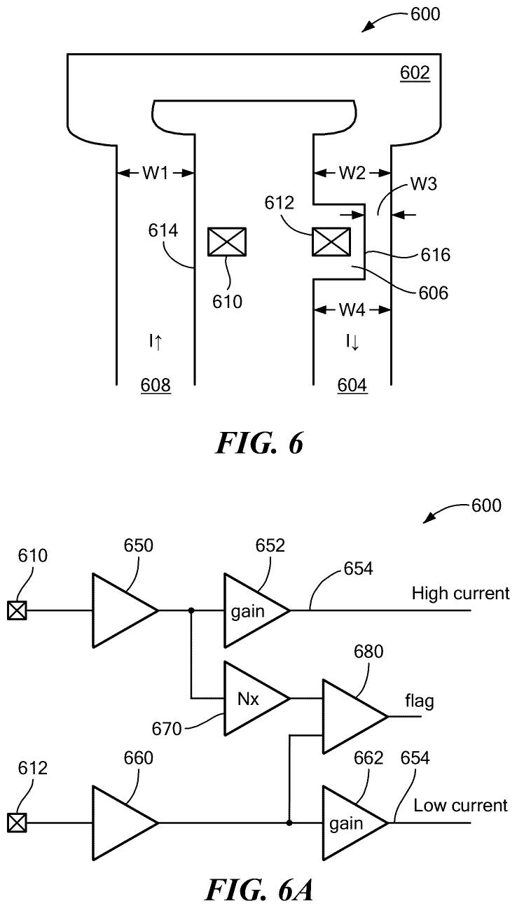

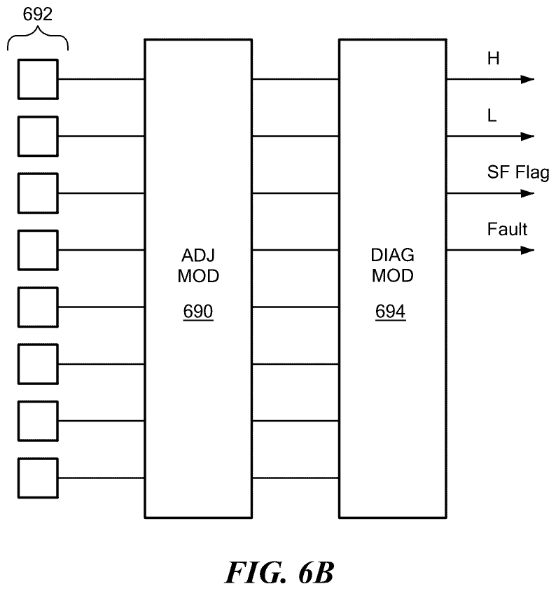

FIG. 6 shows an example embodiment of a portion of a sensor 600 having a U-shaped leadframe 602 configuration for a current sensor having a current conductor for measuring current flow. The direction of current I should follow the U-shape, e.g., flow in a generally linear direction into the U-shape, change direction at the turn in the U-shape, and flow in a generally linear direction out of the U-shape, or vice-versa. The current flow characteristics in relation to the position of the magnetic field sensing elements can be controlled by a geometry of the leadframe to meet the needs of a particular application.

A first side 604 of the U-shaped leadframe has a narrowed region 606 and a second side 608 is without a narrowed region, e.g., has a width that is consistent. In example embodiments, first and second Hall effect magnetic field sensing elements 610, 612 are positioned in relation to edges of first and second portions of the leadframe to enable detection of stray fields or other anomalies.

In the illustrated embodiment, the first magnetic field sensing element 610 is positioned in relation to the edge 614 of the second side 608 of the conductive U-shaped leadframe and the second magnetic field sensing element 612 is contained at least partly within the narrowed region 606, such as a notch, and positioned in relation to an edge 616 of the bottom of the notch.

In the illustrated embodiment, the second side 608 of the leadframe has a consistent width W1 and the first side 604 of the leadframe with the narrowed region 606 has a second width W2 above the notch, a third width W3 at the notch, and a fourth width W4 underneath the notch.

In the illustrated embodiment, the first width W1 of the second side 608, a second width W2 above the narrowed region 606, and the fourth width W4 below the narrowed region are the same. In other embodiments, one or more of these widths is different to meet the needs of a particular application. For example, two of these three widths may be the same.

The narrowed region 606 can be formed by any suitable geometry configured to achieve selected current flow characteristics and/or a magnetic field relationship to magnetic field sensing elements. It is understood that the narrowed region 606 can be trough-shaped, round, ovular, triangular-grooved, etc., with any suitable degree of curvature transitioning from one section to another to meet the needs of a particular application.

In an example embodiment, at least one of the first and second Hall plates 610, 612 is biased and/or trimmed, such as during assembly, test, or the like, to detect and/or adjust to the effects of stray fields. For example, as shown and described more fully below, one or both of the first and second Hall plates 610, 612 can be trimmed so that an output voltage from an amplifier circuit configured to receive signals from the Hall plates is the same for each plate. With this arrangement, when the Hall plate signals are processed differentially, a common externally applied field may be cancelled.

FIG. 6A shows an example circuit implementation to adjust an output of one of the magnetic field sensing elements so that similar signals from the sensing elements are received in the absence of a stray field. A first buffer/amplifier 650 receives a signal from the first Hall element 610 on the second (not notched) side 608 of the leadframe and generates a signal to an amplifier 652 for generating an output signal 654 for the high current sensing element.

A second buffer/amplifier 660 receives a signal from the second Hall element 612 on the first (notched) side 604 of the leadframe and generates a signal to an amplifier 662 for generating an output signal 664 for the low current sensing element. It is understood that high and low current are relative terms that correspond to the width of the current loop at which the respective sensing elements are located.

A gain element 670 having a given gain value, e.g., 2x, is coupled to the output of the buffer 650 for the first Hall element 610. The output of the gain element 670 and the output of the second buffer amplifier 660 are fed to a diagnostic module 680, shown as a window comparator, configured to generate a flag. In some embodiments, the window comparator provides the diagnostic module. In example embodiments, the gain value for the gain element 670 is selected to produce the same signal level as the second buffer/amplifier 660 for a given current through the current loop in the absence of a stray field. That is, in the absence of a stray field on the first and second sensing elements 610, 612, the signals to the diagnostic module 680 should be the same to within some defined amount. In this situation, the flag output from the diagnostic module 680 is not active.

If a stray field is present with sufficient strength and orientation on the sensing elements 610, 612, the signals received by the diagnostic module 680 will diverge. If the difference of the signals exceeds the selected defined amount, the flag from diagnostic module 680 is activated to indicate that a stray field is present.

In an example, embodiment, a pair of Hall elements can be located near each other and biased so that a difference of the output signals is zero in the absence of a stray field. One Hall element can be near the notch and the other can be in the notch.

It is understood that a wide range of magnetic field sensing element types, positions, and clustering can be used to meet the needs of a particular application. For example, magnetoresistive (MR) elements can be used instead of, or in addition to Hall elements. For example, but not limited to, the MR element may be used for the notched region sensing element 612, and a Hall element may be used as magnetic field sensing element 610. In some embodiments, signals can be processed in analog and/or digital format. In one embodiment, a diagnostic module, such as module 680 in FIG. 6, can comprise a processor to analyze signals from the magnetic field sensing elements with or without gain elements, such as element 670, for example.

FIG. 6B shows a digital implementation of an adjustment module 690 receiving signals from a series of magnetic field sensing elements 692, which provides adjusted signals to a diagnostic module 694 configured to detect the presence of a stray field. Any practical number of magnetic field sensing elements can be used to meet the needs of a particular application. In embodiments, signals from the sensing elements can be digitized and adjusted prior to determining whether signals have diverged more than a given amount. It is understood that signals can be processed in a wide variety of ways to determine an amount of divergence.

In some embodiments, a high current or a low current sensitivity path can be connected to the output. In one particular embodiment, the output only uses the small current (notched) path. The larger current (no notch/wider conductor portion) will have lower magnetic coupling (G/A) and therefore, will not be as sensitive to the current as the smaller (or narrowed portion) current path with higher magnetic coupling (G/A). It is understood for embodiments using MR sensing elements that there should be consideration of where the low current (notched) signal saturates so that the use of non-MR sensing elements may be desirable when MR signals are saturated. It should be noted that once the signal saturates there will be some level of unknown as to the external field characteristics and generate an alert flag even when no external field is present. In embodiments, a second flag is indicative of low current saturation.

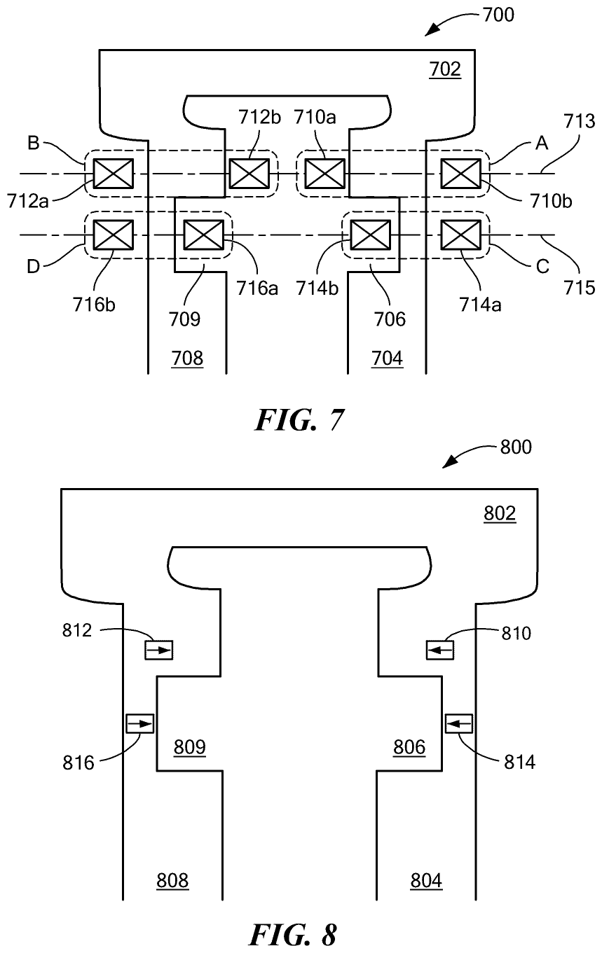

FIG. 7 shows another embodiment of Hall elements positioned in relation to notches formed in both sides of a U-shaped current loop. While the current loop is shown as being symmetric, in other embodiments, the notches may be different in shape and/or size and/or location. As noted above, in the absence of a stray field, the signals from the sensing elements should be controlled to be the same to within some range. In some embodiments, asymmetric notches and/or sensing element positioning may be desirable to detect different stray field orientations. It may be desirable to use sensing elements, or pairs of sensing elements, at the maximum distances from each other to maximize the difference in the stray field that affects the sensing elements. For example, a magnetic source (which may come from, for example but not limited to, an external magnet, or a current flowing through an external conductor) may generate a stray field that causes sensing elements at different distances and orientations to generate different signals in response. In another embodiment, the current conductor may be straight, or non-U-shaped, such as L-shaped, etc., and the Hall plates or MR elements may have sensitivities such that they provide a differential or summation of zero when the applied current is zero without the presence of an external magnetic field.

The illustrated current loop formed in a leadframe 702 includes a first side 704 having a first notch 706 and a second side 708 having a second notch 709. First and second magnetic field sensing elements 710a,b, which are shown as Hall elements, are positioned above first notch 706 in the first side 704 of the loop and third and fourth magnetic field sensing elements 712a,b, which are shown as Hall elements, are positioned above second notch 709 in the second side 708 of the loop. The first and second magnetic field sensing elements 710a,b can be considered as pair A of differential sensing elements and third and fourth magnetic field sensing elements 712a,b can be considered as pair B. In the illustrated embodiment, the first, second, third, and fourth sensing elements 710a,b 712ab are positioned along a first axis 713 perpendicular to the first and second sides 704, 708 of the loop. Further sensing elements are placed along a second axis 715 parallel to the first axis and passing through the first and second notches 706, 709. More particularly, fifth and sixth sensing elements 714a,b (Pair C) are positioned such that the fifth sensing element 714a is outside of the first loop and the sixth sensing element 714b is at least partially contained in the first notch 706. Seventh and eighth sensing elements 716a,b (Pair D) are positioned such that the seventh sensing element 716a is at least partially contained in the second notch 709 and the eighth sensing element 716b is outside of the second loop 709. In another embodiment, the pairs of sensing elements A-B, and C-D may not be aligned along axes as shown, but be at different places along the conductor, for example if the notches are not along the axis 715. MR and Hall elements may both be used for sensing elements. One example may have MR elements for magnetic sensing regions B and D (for MR the sensing elements may move to be over the conductor at the notches if the MR elements are sensing magnetic field parallel to the plane above the current conductor (or parallel to the plane of the die) and planar Hall elements at regions A and C. Other combinations are also possible. In another embodiment the conductor could be made wider around differential pairs A and B to further reduce magnetic coupling (G/A).

In operation, two or more pairs A, B, C, D of sensing elements can be active to meet the needs of a particular application. With no stray field present, each pair A, B, C, D of sensing elements outputs a signal level that is the same for a given current level in the current loop. As described above, one or more of the elements in each pair A, B, C, D, can be biased, trimmed, etc., to achieve a desired output signal. In one embodiment, pairs A and B are active. In another embodiment, pairs A, B, C, and D are active. If any one of the pairs has an output or adjusted output that diverges more than a selected amount, a flag can be generated indicative of stray field detection.

FIG. 8 shows a sensor embodiment 800 having some commonality with the sensor 700 of FIG. 7 with MR elements 810, 812 and 814, 816 instead of Hall elements. The sensitive direction of the sensing elements is indicated by the respective arrows. It is understood that the direction of sensitivity can be changed during manufacturing, testing, etc. In the illustrated embodiment, the MR elements 810, 812, 814, 816 overlap with conductive portions of the leadframe. In other embodiments, the MR elements may be positioned to at least partially overlap with edges of the conductive leadframe. In some embodiments, an MR sensor is sensitive to z-axis fields. In other embodiments MR elements and Hall elements may both be used, for example 810 may be a vertical Hall element and 814 may be an MR element.

In the illustrated embodiment, first and second MR elements 810, 812 are located over a non-narrowed section of the leadframe and third and fourth MR elements 814, 816 are located over narrowed, e.g., notched, regions 806, 809 of the first and second portions 804, 808 of the current loop.

As described above, each of the MR element signals can be adjusted to a given signal level so that deviation can be used to detect a stray field. It is understood that a wide variety of MR element locations, sensitivity axes, and leadframe geometry can be used to meet the needs of a particular application.

Embodiments of the disclosure can be configured to detect stray fields generated by a variety of sources. For example, a stray field may be generated by a wire or circuit in the wrong location, such as erroneous maintenance activity, which may result in unsafe conditions. In some embodiments, with a sufficient number of magnetic field sensing elements, the direction of a magnetic source (for example a permanent magnet or a current through a conductor) generating a stray field may be determined.

In embodiments, a sensor can be tested to confirm that the stray field flag is not active when it is known that there is no stray field present, as well as tested to confirm that the stray field flag becomes active when a stray field of sufficient magnitude is applied. In some embodiments, the magnetic field sensing element adjustment is calibrated to a given divergence corresponding to a given stray field orientation and/or amplitude. In an embodiment a coil, including but not limited to an on-chip coil, may be applied near one or multiple pairs of magnetic field sensing elements. The magnetic field from the coil can be used to cause a difference and test the stray field flag to make sure the system is working as desired. For example, the on-chip coil proximate the first and/or second magnetic field sensing elements can generate a test magnetic field to simulate the stray field. In another embodiment the coil may only be on the differential pair C in FIG. 7, and the current outputs can be taken only from differential pairs B and D, and differential pairs A and C can be used to test the flag or stray field indicator. One advantage of this embodiment is that the analog current levels of the pairs B and D can still provide an output while testing A and C so that current sensing can be provided during testing of the flag or stray field detection circuit with the coil.

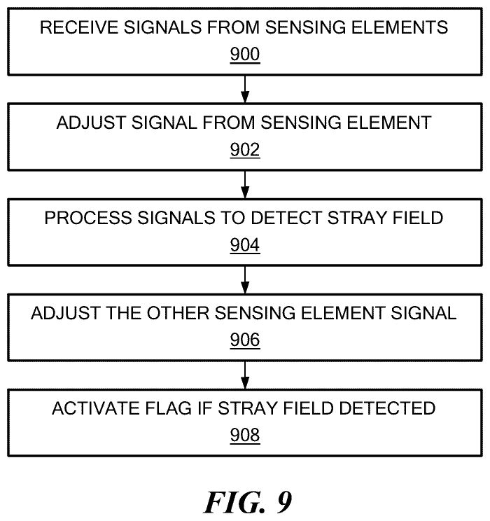

FIG. 9 shows an example sequence of steps for providing a sensor with stray field detection. In step 900, first and second output signals from first and second magnetic field sensing elements are received in a current sensor integrated circuit package having a conductive current loop having regions of different widths. In step 902, the output of the first magnetic field sensing element is adjusted to generate an adjusted signal for the first magnetic field sensing element that is same as the second output signal. In step 904, the adjusted signal for the first magnetic field sensing element and the output of the second output signal are processed to detect a presence of a stray field. In optional step 906, the output of the second magnetic field sensing element is adjusted to generate an adjusted signal for the second magnetic field sensing element for a diagnostic module. In step 908, a flag indicative of a stray field is activated if the adjusted signals diverge by more than a selected amount.

As used herein, the term “magnetic field sensing element” is used to describe a variety of electronic elements that can sense a magnetic field. The magnetic field sensing element can be, but is not limited to, a Hall effect element, a magnetoresistance element, or a magnetotransistor. As is known, there are different types of Hall effect elements, for example, a planar Hall effect element, a vertical Hall effect element, and a Circular Vertical Hall (CVH) element. As is also known, there are different types of ‘magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half-bridge or full (Wheatstone) bridge, configured for single-ended or differential sensing. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb). A coil may also be used to sense magnetic fields, which may be referred to as inductive sensing. Using a coil to sense a magnetic field is more typical as the frequency of the magnetic field to be sensed increases.

As is known, some of the above-described magnetic field sensing elements tend to have an axis of maximum sensitivity parallel to a substrate that supports the magnetic field sensing element, and others of the above-described magnetic field sensing elements tend to have an axis of maximum sensitivity perpendicular to a substrate that supports the magnetic field sensing element. In particular, planar Hall effect elements tend to have axes of sensitivity perpendicular to a substrate, while metal based or metallic magnetoresistance elements (e.g., GMR, TMR, AMR) and vertical Hall effect elements tend to have axes of sensitivity parallel to a substrate.

As used herein, the term “magnetic field sensor” is used to describe a circuit that uses a magnetic field sensing element, generally in combination with other circuits. Magnetic field sensors are used in a variety of applications, including, but not limited to, an angle sensor that senses an angle of a direction of a magnetic field, a current sensor that senses a magnetic field generated by a current carried by a current-carrying conductor, a magnetic switch that senses the proximity of a ferromagnetic object, a rotation detector that senses passing ferromagnetic articles, for example, magnetic domains of a ring magnet or a ferromagnetic target (e.g., gear teeth) where the magnetic field sensor is used in combination with a back-biased or other magnet, and a magnetic field sensor that senses a magnetic field density of a magnetic field.

It is noted that various connections and positional relationships (e.g., over, below, adjacent, etc.) may be used to describe elements in the description and drawing. These connections and/or positional relationships, unless specified otherwise, can be direct or indirect, and the described concepts, systems, devices, structures, and techniques are not intended to be limiting in this respect. Accordingly, a coupling of elements can refer to either a direct or an indirect coupling, and a positional relationship between entities can be a direct or indirect positional relationship. As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s). Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, that includes a list of elements is not necessarily limited to only those elements but can include other elements not expressly listed or inherent to such apparatus, method, composition, mixture, or article.

The terms “one or more” and “at least one” indicate any integer number greater than or equal to one, i.e., one, two, three, four, etc. The term “plurality” indicates any integer number greater than one. The term “connection” can include an indirect “connection” and a direct “connection”.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it may affect such feature, structure, or characteristic in other embodiments whether explicitly described or not.

Use of ordinal terms such as “first,” “second,” “third,” etc., in the claims to modify a claim element does not by itself connote any priority, precedence, or order of one claim element over another, or a temporal order in which acts of a method are performed, but are used merely as labels to distinguish one claim element having a certain name from another element having a same name (but for use of the ordinal term) to distinguish the claim elements.

Having described exemplary embodiments of the disclosure, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A current sensor integrated circuit package comprising:
a current conductor having regions of different widths;
first and second magnetic field sensing elements positioned in relation to the current conductor, wherein the first magnetic field sensing element generates a first output signal and the second magnetic field sensing element generates a second output signal; and
an adjustment circuit to adjust the output of the first magnetic field sensing element to generate an adjusted signal for the first magnetic field sensing element that is same as the second output signal; and
a diagnostic module configured to receive the adjusted signal for the first magnetic field sensing element and the output of the second output signal to detect a presence of a stray field.

2. The package according to claim 1, wherein the current conductor comprises a loop.

3. The package according to claim 2, wherein the loop has a U-shape.

4. The package according to claim 1, further including a further adjustment circuit to adjust the output of the second magnetic field sensing element to generate an adjusted signal for the second magnetic field sensing element for the diagnostic module.

5. The package according to claim 1, wherein the current conductor includes a first width and a narrowed region having a second width less than the first width.

6. The package according to claim 5, wherein the narrowed region comprises a notch.

7. The package according to claim 5, wherein the first magnetic field sensing element is positioned in relation to the narrowed region and the second magnetic field is positioned in relation to a portion of the current conductor having the first width.

8. The package according to claim 7, wherein the current conductor comprises a U-shaped loop having first and second sides and a bottom, wherein the narrowed region is located in the second side of the current loop.

9. The package according to claim 1, wherein the first magnetic field sensing element comprises a Hall element.

10. The package according to claim 1, wherein the first magnetic field sensing element comprises a magnetoresistive element.

11. The package according to claim 10, wherein the second magnetic field sensing element comprises a Hall element.

12. The package according to claim 1, further including an adjustment circuit to adjust the output signal level of the first magnetic field sensing element.

13. The package according to claim 12, wherein the diagnostic module is coupled to the adjustment circuit to detect divergence of the adjusted output signal level of the first magnetic field sensing element and the output signal level of the second magnetic field sensing element more than a selected amount corresponding to the detection of the stray field.

14. The package according to claim 1, wherein the current conductor is linear in shape.

15. The package according to claim 1, further including an on-chip coil proximate the first and/or second magnetic field sensing elements for generating a test magnetic field to simulate the stray field.

16. The package according to claim 1, further including a first terminal to output a first output signal corresponding to the output of the first magnetic field sensing element.

17. The package according to claim 16, further including a second terminal to output a second output signal corresponding to the output of the second magnetic field sensing element.

18. The package according to claim 1, further including an output terminal to output a diagnostic signal indicating the presence of the stray field above a threshold.

19. A method, comprising:
employing a current conductor, which forms part of a current sensor integrated circuit package, having regions of different widths;
positioning first and second magnetic field sensing elements in relation to the current conductor, wherein the first magnetic field sensing element generates a first output signal and the second magnetic field sensing element generates a second output signal; and
adjusting, using an adjustment circuit, the output of the first magnetic field sensing element to generate an adjusted signal for the first magnetic field sensing element that is same as the second output signal; and
configuring a diagnostic module to receive the adjusted signal for the first magnetic field sensing element and the output of the second output signal to detect a presence of a stray field.

20. The method according to claim 19, wherein the current conductor comprises a loop.

21. The method according to claim 20, wherein the loop has a U-shape.

22. The method according to claim 19, further including employing a further adjustment circuit to adjust the output of the second magnetic field sensing element to generate an adjusted signal for the second magnetic field sensing element for the diagnostic module.

23. The method according to claim 19, wherein the current conductor includes a first width and a narrowed region having a second width less than the first width.

24. The method according to claim 23, wherein the narrowed region comprises a notch.

25. The method according to claim 23, wherein the first magnetic field sensing element is positioned in relation to the narrowed region and the second magnetic field is positioned in relation to a portion of the current conductor having the first width.

26. The method according to claim 25, wherein the current conductor comprises a U-shaped loop having first and second sides and a bottom, wherein the narrowed region is located in the second side of the current loop.

27. The method according to claim 19, wherein the first magnetic field sensing element comprises a Hall element.

28. The method according to claim 19, wherein the first magnetic field sensing element comprises a magnetoresistive element.

29. The method according to claim 28, wherein the second magnetic field sensing element comprises a Hall element.

30. The method according to claim 19, further including employing an adjustment circuit to adjust the output signal level of the first magnetic field sensing element.

31. The method according to claim 30, further including coupling the diagnostic module to the adjustment circuit to detect divergence of the adjusted output signal level of the first magnetic field sensing element and the output signal level of the second magnetic field sensing element more than a selected amount corresponding to the detection of the stray field.

32. The method according to claim 19, wherein the current conductor is linear in shape.

33. The method according to claim 19, further including locating an on-chip coil proximate the first and/or second magnetic field sensing elements for generating a test magnetic field to simulate the stray field.

34. The method according to claim 19, further including a first terminal to output a first output signal corresponding to the output of the first magnetic field sensing element.

35. The method according to claim 34, further including a second terminal to output a second output signal corresponding to the output of the second magnetic field sensing element.

36. The method according to claim 19, further including providing an output terminal to output a diagnostic signal indicating the presence of the stray field above a threshold.
